(19) United States
(12) Patent Application Publication
(10) Pub. No.: US 2026/0232107 A1
(43) Pub. Date: Aug. 13, 2026

(54) Adjustable Cable Tray for Desk

(71) Applicant: Desky Pty Ltd, Darra QLD (AU)

(72) Inventors: John Richard Beaver, Darra (AU); Fergus William McKenzie, Rochedale South (AU)

(73) Assignee: Desky Pty Ltd, Darra QLD (AU)

(21) Appl. No.: 19/173,991

(22) Filed: Apr. 9, 2025

(30) Foreign Application Priority Data
Feb. 13, 2025 (AU) 2025200994

(51) Int. Cl. A47B 21/06

(52) U.S. Cl. CPC A47B 21/06; A47B 2021/066

(57) ABSTRACT

Some embodiments relate to a cable tray for a desk, a kit for forming the cable tray and to a desk including the cable tray. An example cable tray comprises: a first element and a second element which cooperate to define front and back walls of the tray, where the first element defines a first portion of the front wall and a first portion of the back wall, the first back wall portion defining a first cable aperture, and where the second element defines a second portion of the front wall and a second portion of the back wall, the second back wall portion defining a second cable aperture. The first and second elements are configured to slidingly engage each other to be telescopically adjustable between: a first extension configuration in which the first cable aperture is not overlapped by the second cable aperture or the second portion of the back wall and the second cable aperture is not overlapped by the first cable aperture or the first portion of the back wall so as to allow passage of separate cables through each of the first and second cable apertures, and a second extension configuration in which the first and second cable apertures overlap to allow passage of cables through both the first and second cable apertures simultaneously.

### CROSS-REFERENCE TO RELATED APPLICATIONS

This application claims the benefit of priority from Australian Patent Application No. 2025200994 filed Feb. 13, 2025, the entire contents of which is hereby incorporated by reference.

### TECHNICAL FIELD

Embodiments relate to a cable tray for desk. In particular, a cable tray configured to be mounted under a desk to accommodate cables, and adjustable to different lengths.

### BACKGROUND

Some desks are fitted with cable trays (typically on an underside of the desk) to accommodate cables (e.g., power and/or communication cables) for equipment to be used on the desk. This facilitates cable management, and assists with keeping the cables safe and tidy.

It is desired do address or ameliorate one or more shortcomings or disadvantages associated with existing cable trays, or to at least provide a useful alternative.

Throughout this specification, the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

Any discussion of documents, acts, materials, devices, articles or the like that has been included in the present specification is not to be taken as an admission that any or all of these matters form part of the prior art base or were common general knowledge in the field relevant to the present disclosure as it existed before the priority date of each of the appended claims.

### SUMMARY

Some embodiments relate to a cable tray for a desk, the cable tray comprising:
a first element and a second element which cooperate to define front and back walls of the tray,
wherein the first element defines a first portion of the front wall and a first portion of the back wall, the first back wall portion defining a first cable aperture,
wherein the second element defines a second portion of the front wall and a second portion of the back wall, the second back wall portion defining a second cable aperture,
wherein the first and second elements are configured to slidingly engage each other to be telescopically adjustable between:
   a first extension configuration in which the first cable aperture is not overlapped by the second cable aperture or the second portion of the back wall and the second cable aperture is not overlapped by the first cable aperture or the first portion of the back wall so as to allow passage of separate cables through each of the first and second cable apertures, and
   a second extension configuration in which the first and second cable apertures overlap to allow passage of cables through both the first and second cable apertures simultaneously.

In some embodiments, the second back wall portion further defines a third cable aperture, and the first and second elements are adjustable to a third extension configuration in which the first and third cable apertures overlap to allow passage of cables through both the first and third cable apertures simultaneously.

In some embodiments, the length of each of the first and second elements, and locations of the cable apertures in the first and second elements, are selected such that each of the extension configurations corresponds to a predetermined extension length of the cable tray.

In some embodiments, at least part of the second element is configured to be received within part of the first element.

In some embodiments, the first element comprises:
a front track at or near a top edge of the first front wall portion configured to accommodate at least part of a top edge of the second front wall portion of the second element; and
a back track at or near a top edge of the first back wall portion configured to accommodate at least part of a top edge of the second back wall portion of the second element.

In some embodiments, the first cable aperture is smaller than the second cable aperture. The first cable aperture may have a same length as the second cable aperture. The first cable aperture may have a smaller height than the second cable aperture. The height of the first cable aperture may be between 10% and 20% less than the height of the second cable aperture.

In some embodiments, the first cable aperture is similar in shape to the second cable aperture.

In some embodiments, the cable tray further comprises a lock mechanism configured to selectively lock the relative position of the first and second elements in a selected one of the extension configurations.

In some embodiments, the first element comprises a first mounting portion at or near a first end of the cable tray and the second element comprises a second mounting portion at or near a second end of the cable tray, the first and second mounting portions being configured to engage corresponding mounting portions on a desk to couple the cable tray to the desk.

In the first element, the first portion of the front wall may define a first power board aperture configured to allow insertion and retention of a first power board in the first power board aperture. In the second element, the second portion of the front wall may define a second power board aperture configured to allow insertion and retention of a second power board in the second power board aperture. The first portion of the front wall may further define a third power board aperture configured to allow insertion and retention of a third power board in the third power board aperture. Each of the first and second elements may have multiple power board apertures defined in the front wall. The multiple power board apertures may have different lengths. The power board apertures may have a rectangular slot shape. The first and second cable apertures may have a round-end slot shape.

Some embodiments relate to a kit comprising a desk frame and a cable tray according to any one of the described embodiments. The kit may additionally include at least one power board configured to be received in one of the power board apertures.

### BRIEF DESCRIPTION OF DRAWINGS

Embodiments are described below, for illustrative purposes only, with reference to the drawings, in which:

FIG. 1A is a perspective view of a cable tray, according to some embodiments;

FIG. 1B is a perspective view of the cable tray of FIG. 1A in a disassembled configuration;

FIG. 1C is a set of orthographic drawings of the cable tray of FIG. 1A in a disassembled configuration showing (from left then top to bottom) an end view, top view, front view, and back view;

FIG. 1D is a close up perspective view of an end of the cable tray of FIG. 1A;

FIG. 1E is a close up perspective view of a disassembled connection between first and second elements of the cable tray of FIG. 1A;

FIG. 1F is a front view of the cable tray of FIG. 1A in a first configuration;

FIG. 1G is a front view of the cable tray of FIG. 1A in a second configuration;

FIG. 1H is a front view of the cable tray of FIG. 1A in a third configuration;

FIG. 1I is a cross-sectional view illustrating the first portion of the cable tray accommodated within the second portion of the cable tray of FIG. 1A;

FIG. 2A is a rear view of the cable tray of FIG. 1A installed on a first desk in a first configuration;

FIG. 2B is a rear view of the cable tray of FIG. 1A installed on a second desk in a second configuration;

FIG. 2C is a rear view of the cable tray of FIG. 1A installed on a third desk in a third configuration;

FIG. 3A is a perspective view illustrating installation of power boards in the cable tray of FIG. 1A, according to some embodiments;

FIG. 3B is a close up perspective view of a power board installed in the cable tray;

FIG. 3C is a cross-sectional view of the cable tray with power board installed illustrating clips to hold the power board in place;

FIG. 4A is an end view of a desk with cable tray partially installed, hingedly connected to the frame of the desk;

FIG. 4B is a close up of the end view of FIG. 4A;

FIG. 4C is a cross-section through a mounting bracket of the frame;

FIG. 4D is a perspective view of the cable tray in a locked configuration mounted to the mounting bracket;

FIG. 4E is a perspective view of the cable tray in a released, hinged configuration of the cable tray;

FIG. 4F is a perspective view of a spring screw with locking pin extended;

FIG. 4G is a perspective view of the spring screw of FIG. 4F with locking pin retracted; and

FIG. 5 is a bottom perspective view of the cable tray of FIG. 1A connected to a desk, according to some embodiments.

### DESCRIPTION OF EMBODIMENTS

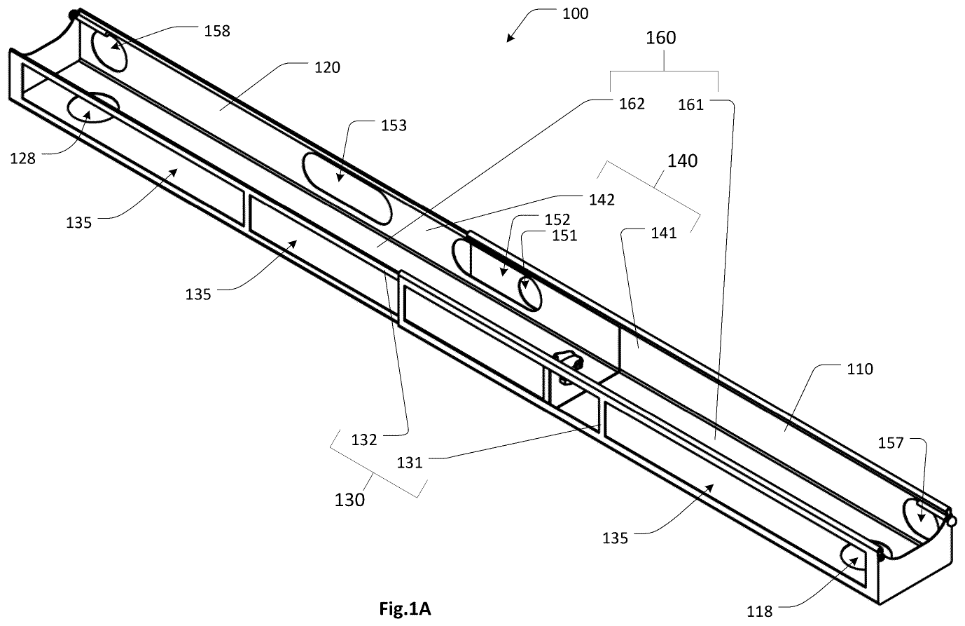

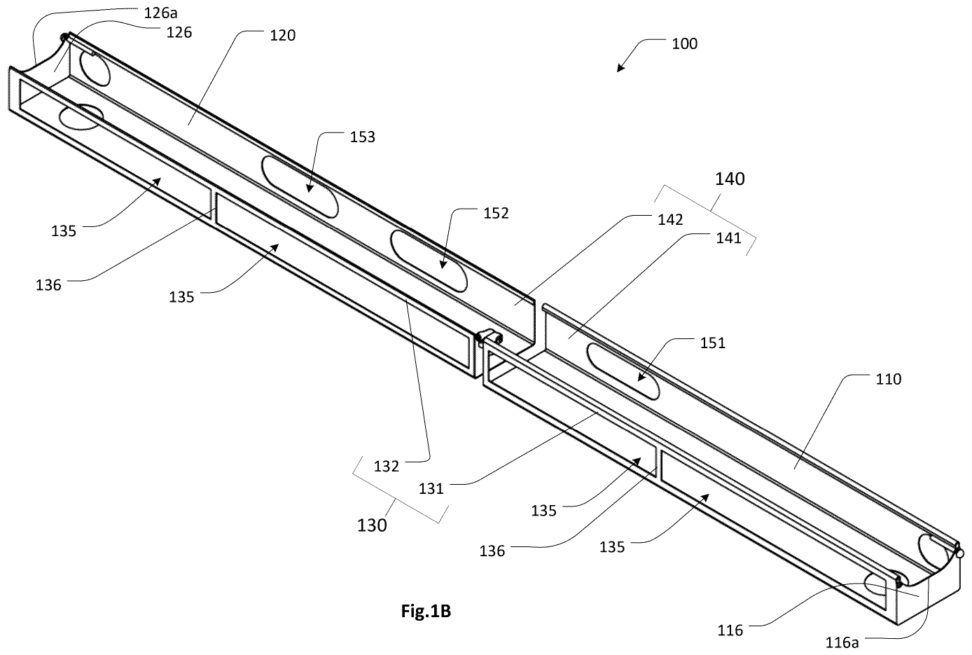

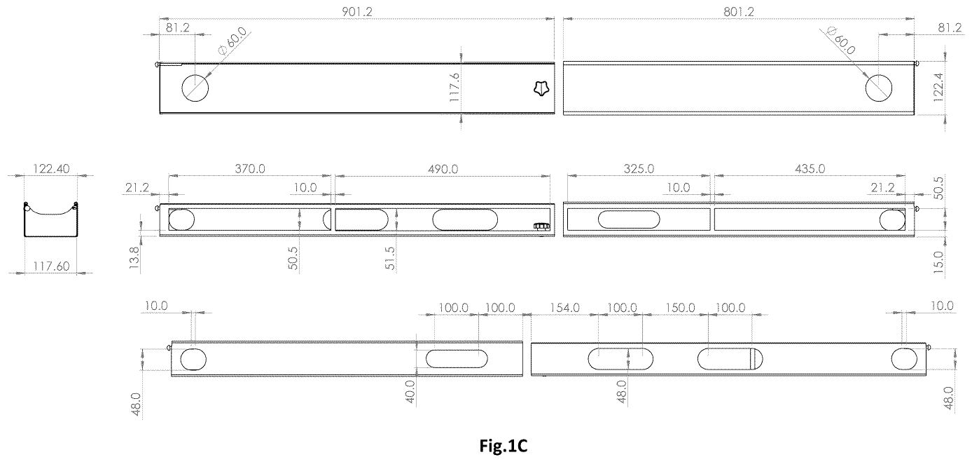

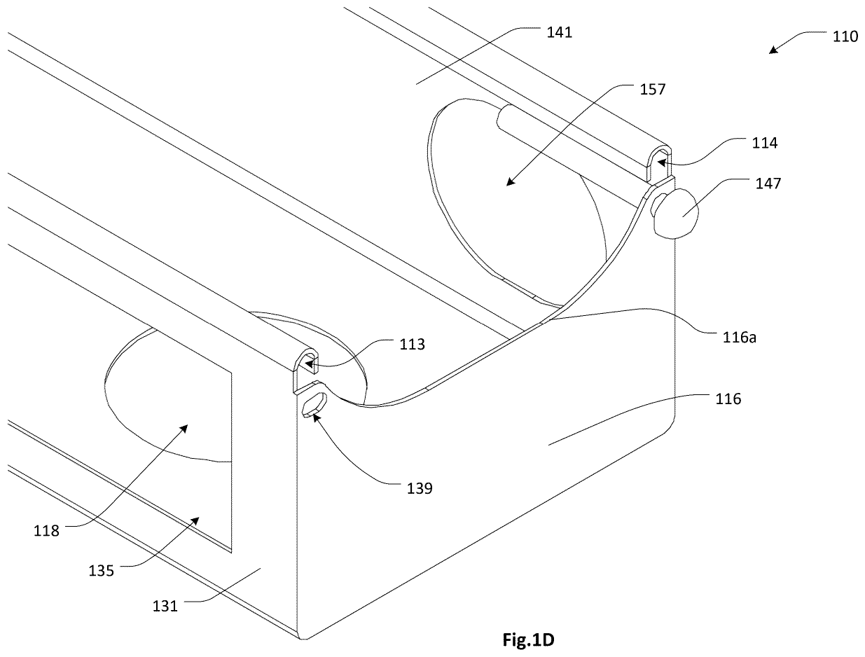

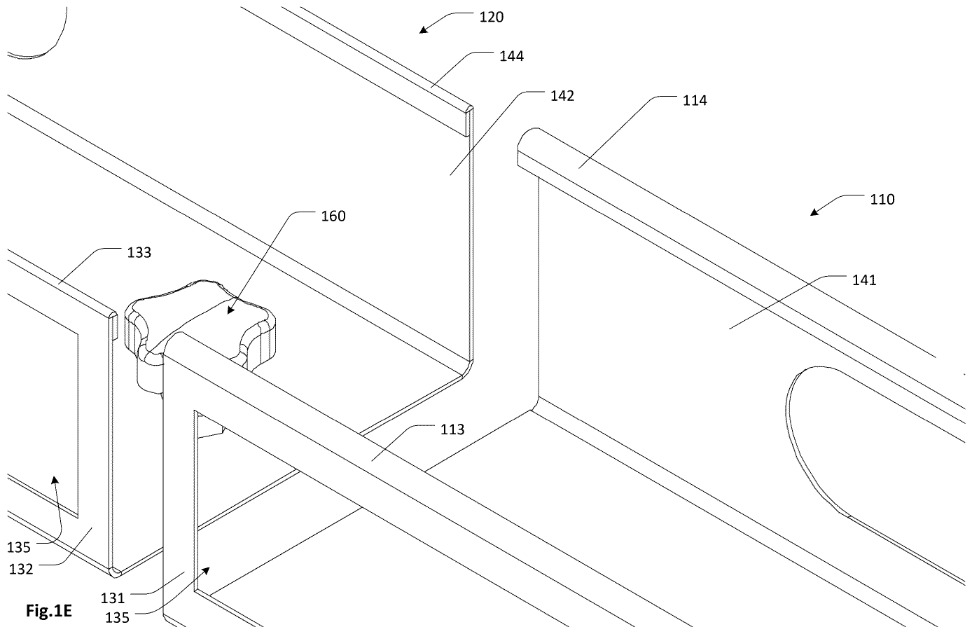

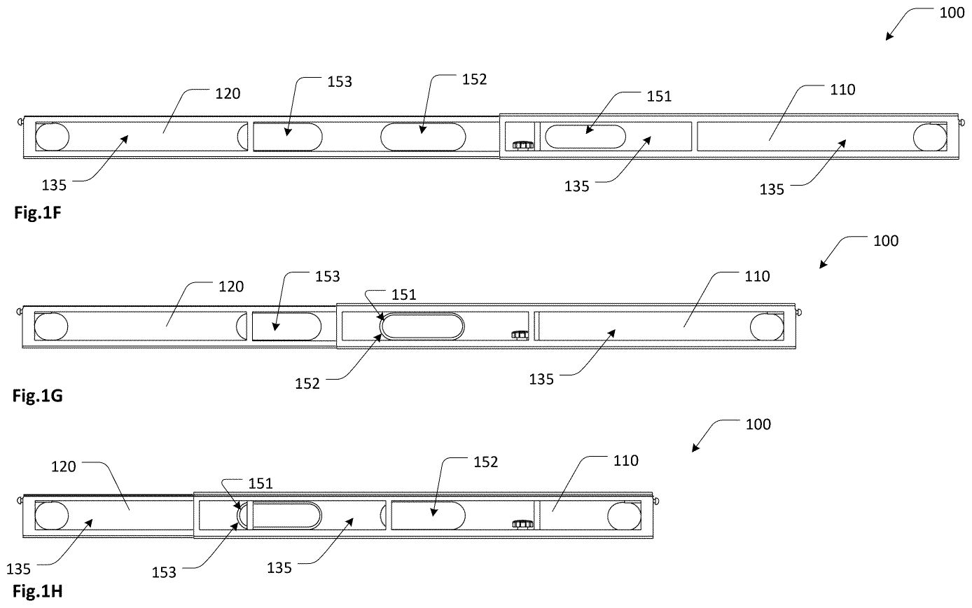

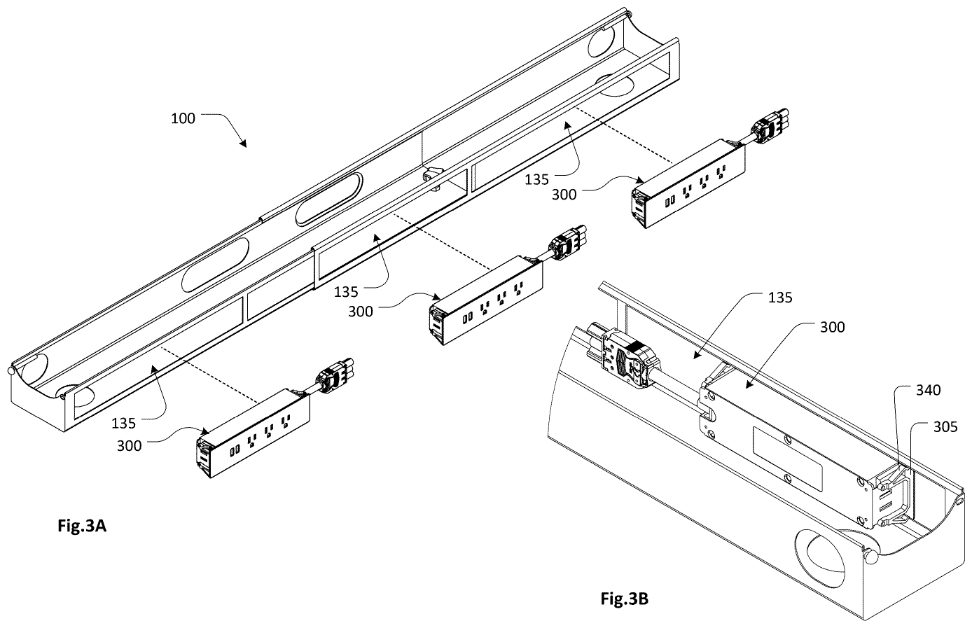

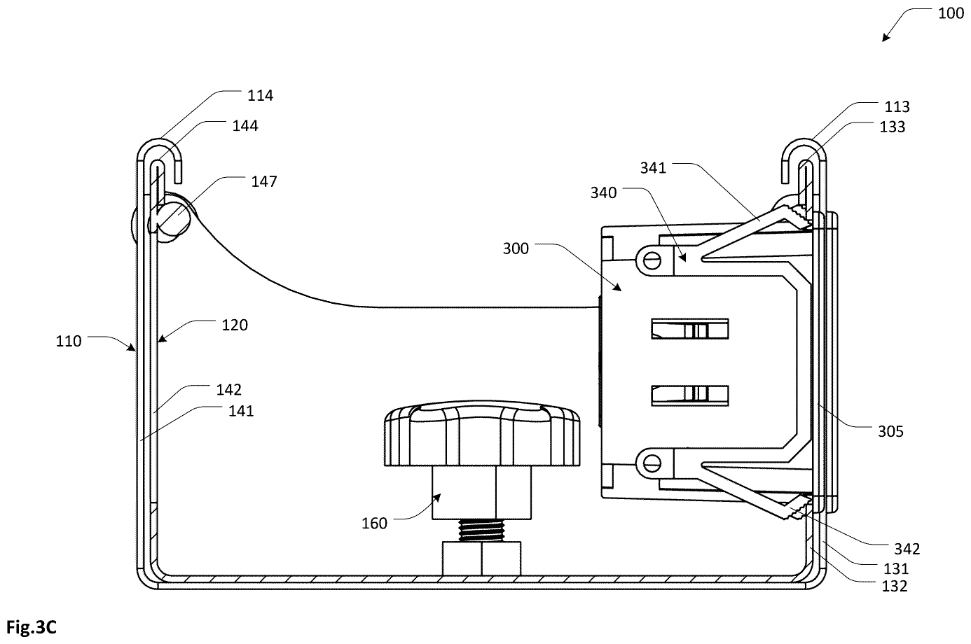

Referring to FIGS. 1A to 1H, a cable tray 100 is shown, according to some embodiments. The cable tray 100 may alternatively be referred to as a cable channel, cable organiser, or cable storage, for example. The cable tray 100 may be mounted to a desk 300 as shown in FIGS. 3A and 3B, for example. The cable tray 100 comprises first and second elements (or parts) configured to be mounted to an underside of the desk to accommodate cables.

Referring to FIG. 1A (assembled) and 1B (disassembled), the cable tray 100 comprises a first element 110 and a second element 120 which cooperate to define a front wall 130 and a back wall 140 of the tray 100. The first element 110 and second element 120 cooperate to define a generally flat bottom wall 160 of the tray 100 extending between the front wall 130 and the back wall 140. The front wall 130, the back wall 140 and the bottom wall 160 cooperate to define a hollow open-topped channel to receive cables, power boards and/or other electrical components. The bottom wall 160 is formed by a first bottom wall portion 161 of the first element 110 and a second bottom wall portion 162 of the second element 120.

The first element 110 has an end wall 116 at one end therefore and an open end at an opposite end thereof. The second element 120 has an end wall 126 at one end thereof and an open end at an opposite end thereof. The open ends are joined in sliding engagement. The end walls 116, 126 of the first and second elements 110, 120 define longitudinally opposite end walls of the cable tray 100. The end walls 116, 126 each have a recessed top edge 116a, 126a that is lower than the top edge of the front and back walls 130, 140 to allow cables to pass over the end wall top edge, if necessary. The first and second end walls 116, 126 may be generally free of apertures.

The first back wall portion 141 may define an additional first end aperture 157 positioned close to the end wall of the first element 110. The second back wall portion 142 may define an additional second end aperture 158 positioned close to the end wall of the second element 120. The additional end apertures 157, 158 of the first or second element 110, 120 may be a relatively small, non-slotted generally circular or square aperture sized to allow a power or data cable to pass therethrough, for example.

The first bottom wall portion 161 may define a first bottom wall aperture 118 positioned close to (but spaced slightly from) the end wall 116 of the first element 110. The second bottom wall portion 162 may define a second bottom wall aperture 128 positioned close to (but spaced slightly from) the end wall 126 of the second element 120. The bottom wall aperture 118, 128 of the first or second element 110, 120 may be a relatively small, non-slotted generally circular or square aperture sized to allow a power or data cable to pass therethrough, for example. The bottom wall 160, including the first and second bottom wall portions 161, 162, may be generally free of apertures other than the first bottom wall aperture 118 and the second bottom wall aperture 128.

The first element 110 may be formed of a substantially continuous body of material that is generally free of apertures other than those described herein. The second element 120 may be formed of a substantially continuous body of material that is generally free of apertures other than those described herein. The material of the first and second elements 110, 120 is preferably metal, such as steel or aluminium, optionally covered with a coating or surface finish. Alternatively, the first and second elements 110, 120 may be formed of a suitable rigid but non-brittle plastic.

The first element 110 defines a first portion 131 of the front wall 101 and a first portion 141 of the back wall 140. The first back wall portion 141 defines a first cable aperture 151 (more clearly shown in FIG. 1B). The first cable aperture 151 may be positioned close to but spaced from the open end of the first element 110.

The second element 120 defines a second portion 132 of the front wall 130 and a second portion 142 of the back wall 140. The second back wall portion 142 defines a second cable aperture 152 (more clearly shown in FIG. 1B). The second cable aperture 151 may be positioned close to but spaced from the open end of the second element 120.

The first and second front wall portions 131, 132 may also define power board apertures 135, as shown in FIGS. 1A and 1B, configured to receive power boards 300 as shown in FIGS. 3A to 3C, for providing electrical power outlets. The power board apertures 135 may be sized and shaped to receive corresponding power boards 300 of corresponding size and shape, as discussed further below in relation to FIGS. 3A to 3B.

The first and second elements 110, 120 are configured to slidingly engage each other to be telescopically adjustable between various extension configurations having different extension lengths. The sliding engagement may be slidably nesting engagement.

The cable tray 100 (and first and second elements 110, 120) may be telescopically adjustable to a first extension configuration in which the first cable aperture 151 is not overlapped by the second cable aperture 152 or the second back wall portion 142 and the second cable aperture 152 is not overlapped by the first cable aperture 151 or the first back wall portion 141, so as to allow passage of separate cables through each of the first and second cable apertures 151, 152, for example, as shown in FIG. 1F.

The cable tray 100 (and first and second elements 110, 120) may also be telescopically adjustable to a second extension configuration in which the first and second cable apertures 151, 152 overlap to allow passage of cables through both the first and second cable apertures 151, 152 simultaneously, for example, as shown in FIG. 1G.

Reference to the cable apertures overlapping throughout the specification includes: any part of one aperture overlapping any part of the other aperture; or the entirety of one aperture overlapping part of the other aperture; or the entirety of one aperture overlapping most of or the entirety of the other aperture, i.e., aligned apertures. The example extension configurations shown in FIGS. 1F to 1H have the cable apertures either aligned (substantially entirely overlapping) or unaligned (not overlapping). Other extension configurations may have partially overlapping cable apertures.

The first cable aperture 151 may have a same length as the second cable aperture 152, which may be approximately 100-140 mm, for example. The first cable aperture 151 may have a smaller height than the second cable aperture 152. For example, the height of the first cable aperture 151 may be about 40 mm and the height of the second cable aperture 152 may be about 48 mm. The height of the first cable aperture 151 may be between 10% and 20% less than the height of the second cable aperture 152.

The power board apertures 135 may be configured to overlap and/or align in one or more of the described configurations to optimise the available aperture space for mounting power boards 300, as described in relation to FIGS. 3A to 3C.

In some embodiments, the second back wall portion 142 further defines a third cable aperture 153. The first and second elements 110, 120 may be adjustable to a third extension configuration in which the first and third cable apertures 151, 153 overlap to allow passage of cables through both the first and third cable apertures 151, 153 simultaneously, for example, as shown in FIG. 1H. The third cable aperture 153 may be positioned to coincide with or overlap a longitudinal mid-point of the second element 120, for example.

In some embodiments, the first and second elements 110, 120 is continually adjustable to any extension length between maximum and minimum extension lengths. In some embodiments, particular extension configurations may be associated with particular alignments or non-alignments of the cable apertures and corresponding extension lengths.

In some embodiments, the length of each of the first and second elements 110, 120, and locations of the cable apertures 151, 152, (153), in the first and second elements 110, 120, may be selected such that each of the extension configurations corresponds to a predetermined extension length of the cable tray 100.

For example, each extension configuration may correspond to a particular arrangement of cable apertures and a corresponding extension length suitable for a particular desk design.

FIG. 1C illustrates a set of dimensions for a cable tray 100, according to some embodiments, which can be adjusted to the first, second and third extension configurations shown in FIGS. 1F, 1G, 1H, respectively.

In the first extension configuration of FIG. 1F, the cable apertures are unaligned (not overlapping) and all three cable apertures 151, 152, 153 are open providing rear access to the cable tray and allowing passage of separate cables through each cable aperture 151, 152, 153.

In the second extension configuration of FIG. 1G, the first and second cable apertures 151, 152 are aligned and substantially entirely overlapping (though not strictly entirely overlapping due to the size difference) allowing passage of cables through the first and second cable apertures 151, 152 together (simultaneously) and/or separately through the third cable aperture 153.

In the third extension configuration of FIG. 1H, the first and third cable apertures 151, 153 are aligned and substantially entirely overlapping (though not strictly entirely overlapping due to the size difference) allowing passage of cables through the first and third cable apertures 151, 153 together (simultaneously) and/or separately through the second cable aperture 152.

In the illustrated embodiment, with dimensions shown in FIG. 1C, the extension length of the cable tray 100 in the first configuration is a first specific length of about 1588 mm. The extension length of the cable tray 100 in the second configuration is a second specific length (shorter than the first specific length) of about 1348 mm. The extension length of the cable tray 100 in the third configuration is a third specific length (shorter than the second specific length) of about 1098 mm. The different extension lengths are selected to suit different desk lengths.

In some embodiments, the lengths of the first and second elements 110, 120 and the relative locations of the cable apertures 151, 152 (153) may be selected such that each of the extension configurations corresponds to a particular alignment of cable apertures and a predetermined extension length of the cable tray 100. This may provide an advantage in making it easier for a user to adjust the cable tray to a desired length (e.g., to suit a particular desk) based on the alignment of cable apertures without having to measure the length.

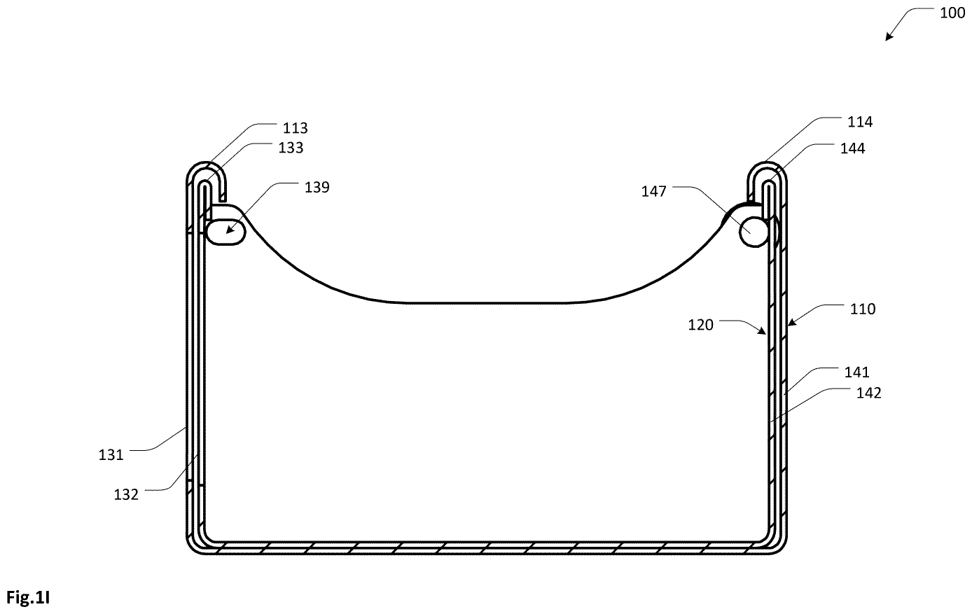

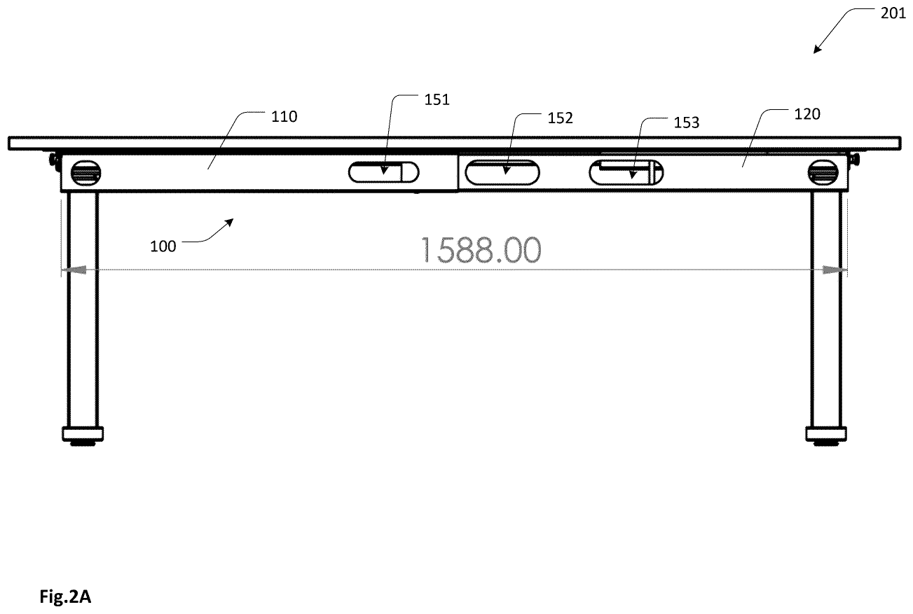

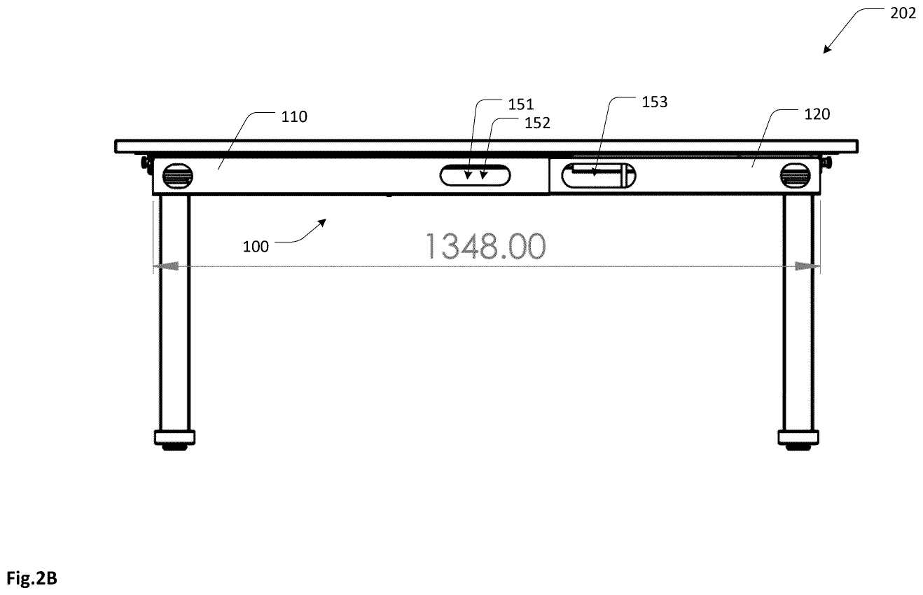

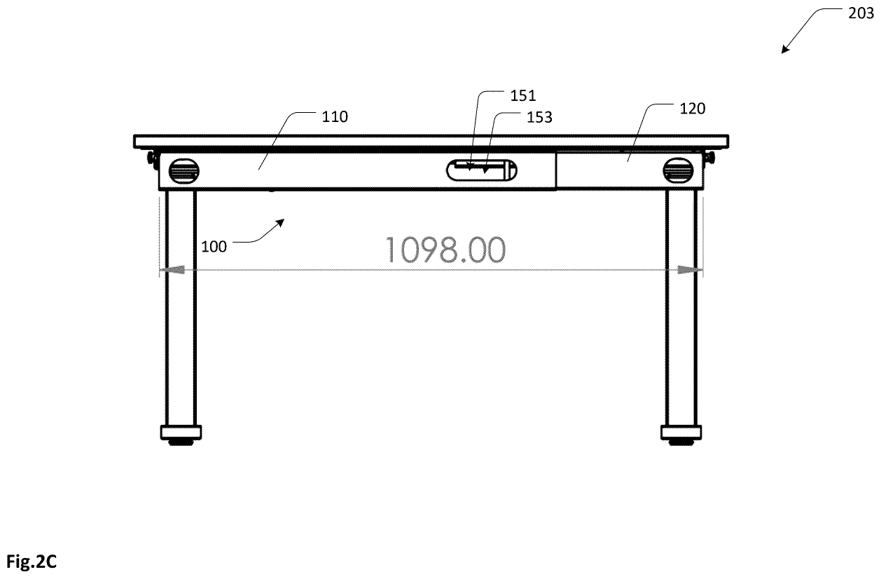

FIGS. 2A, 2B and 2C show rear views of the cable tray 100 installed in the respective first, second and third configurations described above on desks designed with frames corresponding to the extension lengths of each configuration.

FIG. 2A shows the cable tray 100 in the first configuration installed on the frame of an 1800 mm×750 mm desk 201.

FIG. 2B shows the cable tray 100 in the second configuration installed on the frame of a 1500 mm×750 mm desk 202.

FIG. 2C shows the cable tray 100 in the third configuration installed on the frame of a 1200 mm×750 mm desk 203.

The cable tray 100 may also be installed on any other desk with suitable mounting features set at other lengths within the range of extension of the cable tray 100, and may be adjusted to any other suitable extension length, with apertures aligned, misaligned, overlapping, or not overlapping, so that it can be used with desks of different lengths (i.e., other than the lengths associated with the first, second and third configurations described above).

The dimensions of the cable tray 100 may also be adjusted such that the first, second and third configurations are set at particular extension lengths to suit other desk designs.

In some embodiments, the first element (or part thereof) may be configured to be received in the second element. In other embodiments (e.g., as shown in FIGS. 1A to 1H), at least part of the second element 120 may be configured to be received within part of the first element 110.

Referring to FIGS. 1D, 1E and 1I, the first element 110 comprises a front track 113 at or near a top edge of the first front wall portion 131, and a back track 114 at or near a top edge of the first back wall portion 141. For example, in embodiments where the first and second elements are formed of sheet metal (e.g., steel), the front track 113 and back track 114 may be formed by rolling over an edge of the sheet in an inward direction.

Referring to FIGS. 1E and 1I, the front track 113 may be configured to define a narrow channel to accommodate at least part of a top edge 133 of the second front wall portion 132 of the second element 110, and the back track 114 may be configured to define a narrow channel to accommodate at least part of a top edge 144 of the second back wall portion 142 of the second element 120. For example, in embodiments where the first and second elements are formed of sheet metal (e.g., steel), the top edges 133,144 of the second element 120 may be formed by folding over an edge of the sheet in an inward direction and folding the sheet against itself to strengthen the top edges 133, 144.

The profile of the second element 120 fits into the profile of the first element 110 like a drawer, and can be slid along the first element 110 to adjust the extension length of the cable tray 100.

In some embodiments, the first and second elements 110, 120 may be configured with a relatively tight fit so that the friction between them is sufficient to resist significant bending when mounted by the ends of the cable tray 100.

In some embodiments, the cable tray 100 may further comprise a lock mechanism configured to selectively lock the relative position of the first and second elements in a selected one of the extension configurations. The lock mechanism may also contribute to resisting bending of the cable tray 100 when installed.

The lock mechanism 160 shown in the illustrated embodiment (e.g. as shown in FIGS. 1E to 1H) comprises an adjustment screw threadedly engaged with the second element 120 and configured to press against the first element 110 when tightened to increase the friction between the first and second elements 110, 120 (e.g., between the tracks 113, 114 and top edges 133, 144). Alternatively, the adjustment screw could be threadedly engaged with the first element 110 and configured to press against the second element 120. Alternatively, the adjustment screw could be configured to draw parts of the first and second elements 110, 120 to increase friction between them.

The lock mechanism may alternatively comprise any other suitable retention mechanism to retain the first and second elements 110, 120 in a selected position relative to each other. For example, as the lock mechanism may include a sprung latch on one element configured to engage one or more catches on the other element. The lock mechanism may be positioned close to, but slightly spaced from, the open end of the second element 120, for example.

In some embodiments, the cable apertures 151, 152, 153 may be substantially similar in size and shape. In some embodiments, such as the cable tray 100 shown in FIGS. 1A to 1I, the first cable aperture 151 is smaller than the second cable aperture 152.

Once the cable tray 100 is adjusted to a desired extension length or configuration, power boards 300 may be mounted in power board apertures 135 formed in the front wall 130, as shown in FIGS. 3A to 3C.

In the first element 110, the first portion 131 of the front wall 130 may define a first power board aperture 135 configured to allow insertion and retention of a first power board 300. In the second element 120, the second portion 132 of the front wall 130 may define a second power board aperture 135 configured to allow insertion and retention of a second power board 300. The first portion 131 of the front wall 130 may further define a third power board aperture 135 configured to allow insertion and retention of a third power board 300. The second portion 132 of the front wall 130 may further define a fourth power board aperture 135 configured to allow insertion and retention of a fourth power board 300.

Each of the first and second elements 110, 120 may have multiple power board apertures 135 defined in the front wall 130. The multiple power board apertures 135 may collectively or each have different longitudinal lengths. The front wall 130 includes vertically extending portions 136 in between the power board apertures 300, which may act as supports, bars or stanchions between an upper part and a lower part of the front wall 130 that are otherwise separated by the power board apertures 135, for example as shown in FIG. 1B.

The power board apertures 135 may have a rectangular slot shape. The first, second and third cable apertures 151, 152, 153 may each have a round-end slot shape.

The power boards 300 shown are specifically designed for use with the illustrated cable tray 100. Other power boards may be designed to fit other power board apertures in other embodiments based on a similar concept.

The power boards 300 each include a generally rectangular body 301 with a height suited to closely fit within the height of the power board apertures 135 of the cable tray 100. Each power board 300 also includes a face plate 305 (which may or may not be integrally formed with the body 301). The face plate 305 is taller than the power board apertures 135, so that they do not pass through when oriented parallel to the front wall 130.

The power boards 300 also include clips 340 configured to pass through the power board apertures 135, and then lock in place to resist removal of the power boards 300 from the power board apertures 135.

The clips 340 each comprise a first leg 341 and a second leg 342 which extend upwards and downwards, respectively, at an angle relative to the body 301, such that the distance between the further points of the legs 341, 342 is greater than the height of the power board apertures 135 in a biased configuration of the clips 340.

The legs 341, 342 of the clips 340 are resiliently deformable, such that, when the power boards 300 are pushed through the power board apertures 315, the legs 341, 342 are deflected inwards, towards each other, to pass through the power board apertures 135 then, once through, return (at least partially) towards the biased configuration to press against the front wall 130 from the inside of the cable tray 100 and resist removal of the power boards 300 from the power board apertures 135. The power boards 300 may be removed from the power board apertures 135 by manually deflecting the legs 341, 342 of the clips towards each other to a point at which they can pass back through the power board apertures 135.

In some embodiments, each of the legs 341, 342 may further comprise a foot angled back towards a centre of the face plate 305 to provide an angled surface to press against the front wall 130 at or near an edge of the power board apertures 135.

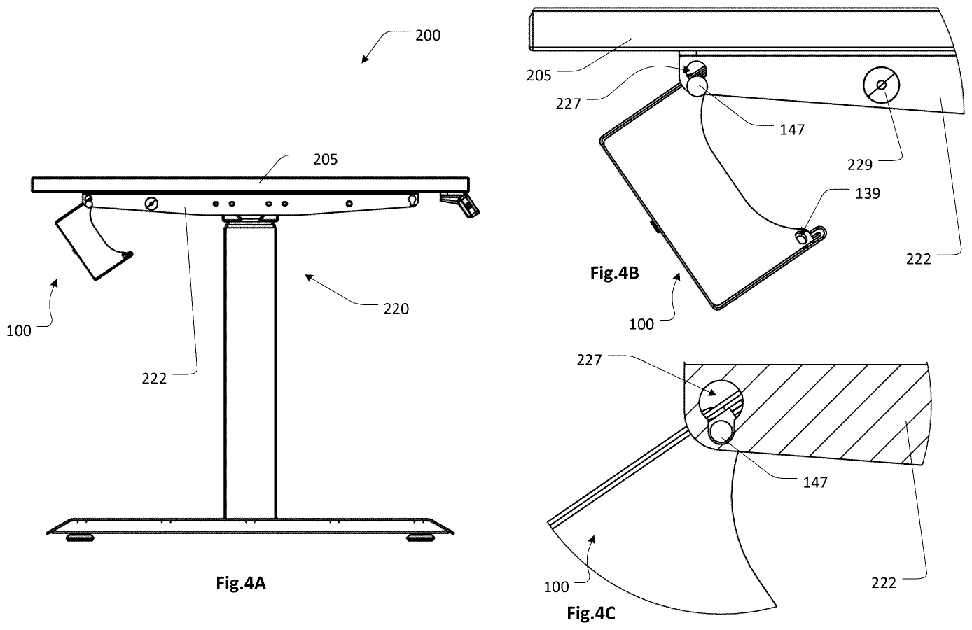

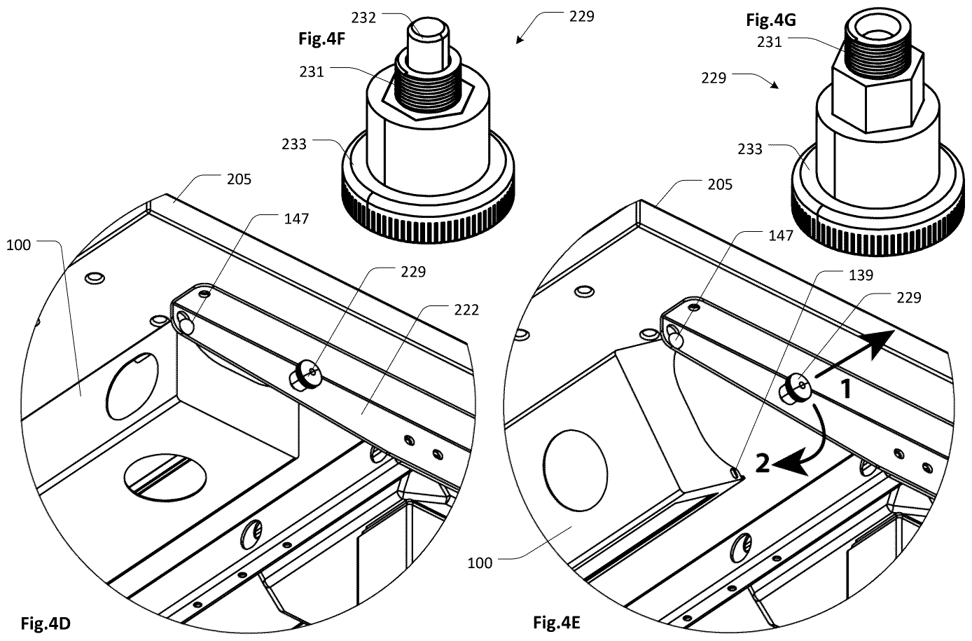

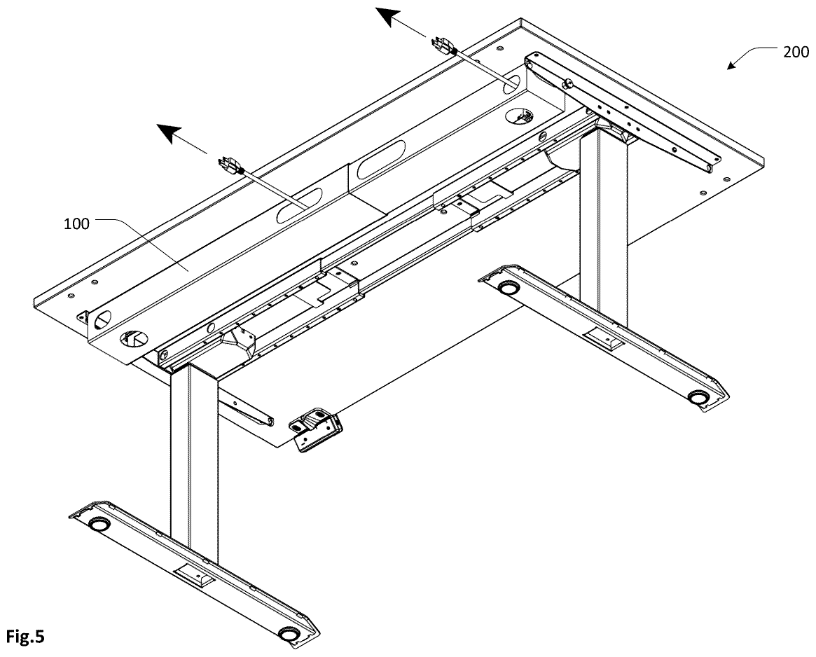

Referring to FIGS. 4A to 4G, a mounting system for the cable tray 100 is shown for illustrative purposes, according to some embodiments.

The first element 110 may comprise a first mounting portion at or near a first end of the cable tray 100 and the second element 120 may comprise a second mounting portion at or near a second end of the cable tray 100. The first and second mounting portions are configured to engage corresponding mounting portions on a desk to couple the cable tray 100 to the desk.

FIG. 4A is an end view of the cable tray 100 partially mounted to a desk 200 by hinging mounting portions, described below. This allows the cable tray 100 to be swung down from the desk top 205, as shown, to inspect, reconnect or reorganise cables without fully removing the cable tray 100 from the desk 200.

The cable tray 100 comprise a hinge pin 147 at each end at or near the back wall 140 comprising a short length of rod with a relatively large head. The frame 220 of the desk 200 comprises a mounting bracket 222 defining a keyhole slot 227 configured to receive the head of the hinge pin 147 and allow the rod of the hinge pin 147 to seat down into a relatively narrower portion of the keyhole slot 227.

The frame 220 further comprises a spring screw 229 in the bracket 222 at each end of the desk to engage a mounting aperture 139 in the cable tray 100. When the cable tray 100 is hingedly mounted to the frame 220 by the hinge pins 147, it can be swung up towards the desk top 205 as shown in FIG. 4D, and selectively locked in position by the spring screws 229 extending into the mounting apertures 139.

The spring screws 229 are shown in further detail in FIGS. 4F and 4G. Each spring screw 229 comprises a threaded portion 231 configured to engage a corresponding threaded portion on the mounting bracket 222 to mount the spring screw 229 on the mounting bracket 222.

Each spring screw 229 further comprises a locking pin 232 configured to extend through the mounting bracket 222 and into the mounting aperture 139 of the cable tray 100 to lock the cable tray 100 in place relative to the mounting bracket 222.

The locking pin 232 is connected to a knob 233 to manually release the locking pin 232.

An internal spring (not shown) biases the spring screw 229 to a locking position (as shown in FIG. 4F), to lock the cable tray 100 in place (as shown in FIG. 4D), and the knob 233 can be pulled (as shown by arrow 1 in FIG. 4E) to withdraw the locking pin 232 (as shown in FIG. 4G) and disengage from the mounting aperture 139 of the cable tray 100 allowing the cable tray 100 to swing down (as shown by arrow 2 in FIG. 4E).

The mounting system illustrated provides an advantage in that the cable tray does not need to be fastened directly to the desk with conventional mechanical fasteners such as screws. The hinge pin and locking pin mounting portions significantly simplify assembly and disassembly, and allow partial disassembly for reorganising the cables or adding new cables in the hinged configuration without having to remove the cable tray entirely from the desk.

FIG. 5 shows the installed cable tray 100 locked in place mounted on the mounting bracket 222 of the desk 200. Once installed, cables can be fed through the cable apertures in the back walls 141, 142 as shown.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A cable tray for a desk, the cable tray comprising:
a first element and a second element which cooperate to define front and back walls of the tray,
wherein the first element defines a first portion of the front wall and a first portion of the back wall, the first back wall portion defining a first cable aperture,
wherein the second element defines a second portion of the front wall and a second portion of the back wall, the second back wall portion defining a second cable aperture,
wherein the first and second elements are configured to slidingly engage each other to be telescopically adjustable between:
a first extension configuration in which the first cable aperture is not overlapped by the second cable aperture or the second portion of the back wall and the second cable aperture is not overlapped by the first cable aperture or the first portion of the back wall so as to allow passage of separate cables through each of the first and second cable apertures, and
a second extension configuration in which the first and second cable apertures overlap to allow passage of cables through both the first and second cable apertures simultaneously.

2. The cable tray of claim 1, wherein the second back wall portion further defines a third cable aperture, and the first and second elements are adjustable to a third extension configuration in which the first and third cable apertures overlap to allow passage of cables through both the first and third cable apertures simultaneously.

3. The cable tray of claim 1, wherein the length of each of the first and second elements, and locations of the cable apertures in the first and second elements, are selected such that each of the extension configurations corresponds to a predetermined extension length of the cable tray.

4. The cable tray of claim 1, wherein at least part of the second element is configured to be received within part of the first element.

5. The cable tray of claim 4, wherein the first element comprises:
a front track at or near a top edge of the first front wall portion configured to accommodate at least part of a top edge of the second front wall portion of the second element; and
a back track at or near a top edge of the first back wall portion configured to accommodate at least part of a top edge of the second back wall portion of the second element.

6. The cable tray of claim 1, wherein the first cable aperture is smaller than the second cable aperture.

7. The cable tray of claim 6, wherein the first cable aperture has a same length as the second cable aperture, and wherein the first cable aperture has a smaller height than the second cable aperture.

8. The cable tray of claim 7, wherein the height of the first cable aperture is between 10% and 20% less than the height of the second cable aperture.

9. The cable tray of claim 1, wherein the first cable aperture is similar in shape to the second cable aperture.

10. The cable tray of claim 1, further comprising a lock mechanism configured to selectively lock the relative position of the first and second elements in a selected one of the extension configurations.

11. The cable tray of claim 1, wherein the first element comprises a first mounting portion at or near a first end of the cable tray and the second element comprises a second mounting portion at or near a second end of the cable tray, the first and second mounting portions being configured to engage corresponding mounting portions on a desk to couple the cable tray to the desk.

12. The cable tray of claim 1, wherein, in the first element, the first portion of the front wall defines a first power board aperture configured to allow insertion and retention of a first power board in the first power board aperture.

13. The cable tray of claim 12, wherein, in the second element, the second portion of the front wall defines a second power board aperture configured to allow insertion and retention of a second power board in the second power board aperture.

14. The cable tray of claim 12, wherein the first portion of the front wall further defines a third power board aperture configured to allow insertion and retention of a third power board in the third power board aperture.

15. The cable tray of claim 12, wherein each of the first and second elements have multiple power board apertures defined in the front wall, wherein the multiple power board apertures have different lengths.

16. The cable tray of claim 15, wherein the power board apertures have a rectangular slot shape.

17. The cable tray of claim 1, wherein the first and second cable apertures have a round-end slot shape.

18. A kit comprising a desk frame and a cable tray according to claim 1.

19. A kit for forming the cable tray according to claim 1.
